(19) United States
(12) Patent Application Publication
(10) Pub. No.: US 2025/0262976 A1
(43) Pub. Date: Aug. 21, 2025

(54) METHOD AND SYSTEM FOR OFF-GRID TESTING AND DIAGNOSTICS OF A VEHICLE CHARGE STATION

(71) Applicant: Ford Global Technologies, LLC, Dearborn, MI (US)

(72) Inventors: Ryan O'Gorman, Beverly Hills, MI (US); Stuart C. Salter, White Lake, MI (US); Matthew Roseman, Farmington Hills, MI (US); Chandrakant Kulkarni, Canton, MI (US); Patrick Davis, Royal Oak, MI (US); Alexander Avila, Birmingham, MI (US)

(21) Appl. No.: 18/582,036

(22) Filed: Feb. 20, 2024

(51) Int. Cl. B60L 53/68; B60L 53/53; H02J 7/00

(52) U.S. Cl. CPC B60L 53/68; B60L 53/53; H02J 7/00032

(57) ABSTRACT

A method includes supplying, by an electric vehicle (EV), electrical power to an EV charge station, and outputting a message including data indicative of a task result for a software-based task performed at the EV charge station with the EV charge station receiving power from the EV.

### TECHNICAL FIELD

The present disclosure is generally directed to a method of testing a charge station for an electric vehicle.

### BACKGROUND

The statements in this section merely provide background information related to the present disclosure and may not constitute prior art.

Electric vehicles, such as plug-in hybrid vehicles and fully electric vehicles, generally connect to a charge station to charge a high voltage battery pack of the electric vehicle using power from a power grid. In a non-limiting example, the charge station is electrically connected to a building power network, which is connected to the power grid. In some arrangements, the electric vehicle and the charge station are configured to form a bidirectional power transfer system to not only charge the electric vehicle, but to provide power to a power grid, a building, and/or a load.

### SUMMARY

This section provides a general summary of the disclosure and is not a comprehensive disclosure of its full scope or all of its features.

In one form, the present disclosure is directed to a method including supplying, by an electric vehicle (EV), electrical power to an EV charge station, and outputting a message including data indicative of a task result for a software-based task performed at the EV charge station with the EV charge station receiving power from the EV.

In one form, the present disclosure is directed to a system including one or more controllers configured to control a power electronics module to supply electric power to an electric vehicle (EV) charge station from a battery pack of an EV, and output a message including data indicative of a task result for a software-based task performed at the EV charge station with the EV charge station receiving electric power from the EV.

In one form, the present disclosure is directed to a method, including supplying, by an electric vehicle (EV), alternating current (AC) power to an EV charge station after detecting a charger of the EV charge station connected to a charge port of the EV and having the EV charge station electrically isolated from an installed power source; having at least one software-based task performed at the EV charge station after supplying power to the EV charge station; and outputting a message to at least one of a remote server or a human machine interface, the message including data indicative of a task result for the at least one software-based task performed at the EV charge station.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

In order that the disclosure may be well understood, there will now be described various forms thereof, given by way of example, reference being made to the accompanying drawings, in which:

FIG. 1 illustrates a system having at least an electric vehicle and a charge station in accordance with the present disclosure;

FIG. 2 is a flowchart of an example EV test-configuration (EVTC) routine in accordance with the present disclosure; and

FIG. 3 is a flowchart of an example charge station test-configuration (CSTC) routine in accordance with the present disclosure.

The drawings described herein are for illustration purposes only and are not intended to limit the scope of the present disclosure in any way.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

Installation of an electric vehicle charge station can be very complex and, even before the charge station is installed, there can be significant prep work at an installation location to have the charge station connected to a power network at the installation location. Accordingly, if the charge station is faulty, significant resources may be needed to correct the fault. In addition, if the charge station is not faulty and the charge station does not operate as expected, the charge station may be incorrectly flagged for being faulty and the actual issue may not be identified. Furthermore, charge stations that may be in stock but not yet assigned to a location, may need to be routinely tested and/or may need to undergo software updates. Generally, to perform tests and/or perform software updates, the charge station may need to be fully wired to a power source, which is time consuming.

The present disclosure is directed to a method and/or system for performing a software-based task on a charge station without the use of an installed power source (i.e., a power source that is used once the charge station is installed). Specifically, in one form, the method may include supplying, by an EV, electrical power to an EV charge station, and outputting a message including data indicative of a task result for a software-based task performed at the charge station with the charge station receiving power from the EV. That is, with the charge station receiving power from the EV and isolated from the installed power source, the charge station is configured to operate in test-configuration mode to perform, for example, diagnostic test and/or software configuration/updates. Accordingly, the charge station is not required to be wired to the installed power source to detect possible faults and/or to perform software updates.

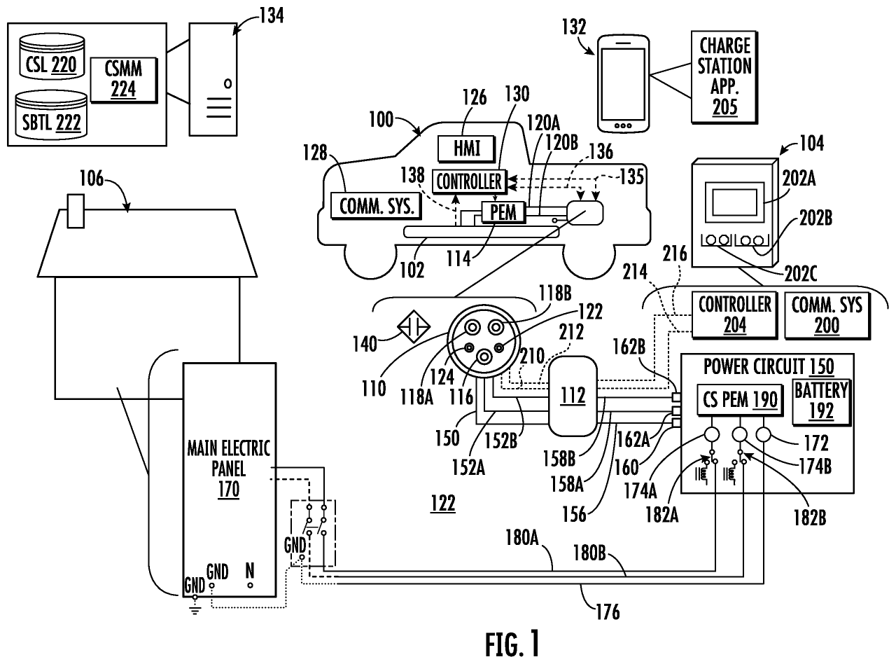

Referring to FIG. 1, an electric vehicle (EV) 100, such as a plug-in hybrid vehicle or a fully electric vehicle, includes a battery pack 102 that is chargeable via a charge station 104, which may also be referred to as an electric vehicle supply equipment. In one form, the EV 100, and the charge station 104 are configured to form a bidirectional power transfer system in which the EV 100 provides power to, for example, a power grid, a house/building, and/or a load (i.e., a device or system receiving power from the EV 100 is referred to as an “electric receiver.”)

The EV 100 includes a charge port 110 configured to connect to a charger 112 of the charge station 104 and a power electronic module (PEM) 114. The charge port 110 is configured to have an EV conductive ground terminal 116 and EV conductive power terminals 118A, 118B (collectively “power terminals” 118) connected to the PEM 114 via power lines 120A, 120B (collectively “power lines 120”), respectively, to receive and output power. In a non-limiting example, the charge port 110 is configured based on EV charger standards, such as but not limited to, combined charging system (CCS).

The PEM 114 is configured to charge the battery pack 102 using power from a power source via the charge station 104 and to supply alternating current (AC) power to an electric receiver. In one form, among other components, the PEM 114 includes an inverter to convert direct current (DC) power from the battery pack 102 to alternating current (AC) power. In a non-limiting example, the power source may be provided as a power network of a building and/or an electrical power grid.

In some variations, in addition to conductive terminals 118, 116, the charge port 110 includes a proximity pin 122 and a control pilot 124 to connect to associated ports on the charger 112. The proximity pin 122 detects the charger 112 indicating the EV 100 is connected to the charge station 104. The control pilot 124 is a communication port to establish digital communication with the charge station 104 using, for example, pulse-width modulation (PWM) per one or more communication standards (e.g., standards IEC 61851-1; DIN SPEC 70121; and/or the ISO/IEC 15118-series).

In one form, the EV 100 further includes one or more human machine interfaces (HMIs) 126, a communication system (Comm. Sys.) 128, and a controller 130. The EV 100 may exchange information with a user via the HMIs 126, which may include, but are not limited to display (e.g., touchscreen display, overhead display), audio system having speaker and microphone, pushbuttons, and/or knobs.

In one form, the communication system 128 is configured to communicate with various external devices/systems using wired and/or one or more wireless communication techniques (e.g., BLUETOOTH, WiFi, ZigBee, Z-Wave, vehicle-to-anything (V2X)). The communication system 128 may also be configured to define a vehicle wireless communication network/hotspot that external devices may join to communicate with other devices/systems. Specifically, as described herein, the charge station 104 and a portable computing device 132 may connect to the vehicle wireless communication network to communicate to each other, and/or to a remote cloud-based server (e.g., charge station server (CSS) 134). Accordingly, the communication system 128 may include a router, a modem, an antenna, an input-output interface, a universal serial bus (USB) port, and/or other suitable devices for wireless and wired communication.

In one form, the controller 130 is configured to control the PEM 114 to charge the battery pack 102 or to supply power to the electric receiver using power from the battery pack 102, as part of a battery pack control process. Specifically, in a non-limiting example, the controller 130 is configured to estimate operating characteristics of the battery pack 102, such as but not limited to, power limit, current, and state of charge (SOC) using sensor data 138. Using the operating characteristics and with the charger 112 connected to the charge port 110 as detected by the proximity pin 122, the controller 130 determines if the battery pack 102 is to be charged or is to provide power to the electric receiver. If the battery pack 102 is to be charged, the controller 130 controls the PEM 114 to charge the battery pack 102 with AC power received via the power lines 120, and if the EV 100 is to supply power, the controller 130 controls the PEM 114 to convert DC power from the battery pack 102 to AC power, which is outputted via the power lines 120.

The controller 130 is configured to detect whether the EV 100 is connected to the charge station 104 via a signal received from the proximity pin 122 provided via communication line 135. The controller 130 is further configured to exchange messages with the charge station 104 via the control pilot 124, which is connected to the controller 130 via communication line 136. In a non-limiting example, the controller 130 exchanges information, such as, but not limited to, a state of charge of the battery pack 102, an electric current measurement of the battery pack 102, whether the battery pack 102 is to be charged, and/or is able to supply power.

In one form, the controller 130 is further configured to operate in a charge station test-configuration (CSTC) mode to assist in executing one or more software-based tasks at the charge station 104. As detailed herein, when in a test-configuration (TC) mode, the charge station 104 may perform software-based tasks, such as, but not limited to: a diagnostic test to test operation of the charge station 104 and/or specific components (e.g., tests directed to checking communication links, response of circuit board, and/or performance of a component); and/or software downloads for software configuration and/or updates. Under these scenarios, the EV 100 may be used to supply power to the charge station 104 and the controller 130 may initiate the CSTC mode to: instruct the charge station 104 to perform one or more software-based task, provide the vehicle WiFi hotspot, and/or communicate with the CSS 134 to exchange one or more messages regarding the charge station 104 and the tasks being performed. In a non-limiting example, the controller 130 may initiate the CSTC mode by receiving a signal indicative of a CSTC switch 140 being operated and/or a message from the charge station 104 indicating the station 104 is in a TC mode received via the control pilot 124.

In one form, the charge station 104 is configured as a level 1 or level 2 EV charger. The charger 112 is configured to electrically couple the ground terminal 116 and the power terminals 118 of the charge port 110 with a power circuit 150 of the charge station 104. In FIG. 1 lines 152, 154A, 154B represent electrical coupling of the ground terminal 116 and power terminals 118 to associated terminals of the charger 112, and lines 156, 158A, and 158B represent electrical coupling of the terminals of the charger 112 to a ground terminal 160 and power terminals 162A, 162B of the power circuit 150.

In a non-limiting example, the charge station 104 may be installed at or near a building and connects to a building power network 170, which is generally illustrated as a main electric panel in FIG. 1. While FIG. 1 illustrates the building as a house, the present disclosure is applicable to charge stations 104 arranged at various locations including, but not limited to, parks, shopping centers, office buildings, parking garages, and/or apartment complexes, and should not be limited to single family dwellings. In this example, the building power network 170 is provided as the installed power source from which the EV 100 draws power via the charge station 104 to charge the battery pack 102.

When installed, the power circuit 150 terminals 172 and 174A, 174B are electrically coupled to a ground line 176 and power lines 180A, 180B that are electrically coupled to the build power network 170. In one form, relays 182A, 182B are provided between the terminals 174A, 174B to electrically couple the charge station 104 to the build power network 170 or decouple the charge station 104 from the build power network 170 to isolate the charge station 104. Specifically, the charger station 104 may be electrically isolated from the build power network 170 when the EV 100 provides power from the battery pack 102 to the charge station 104.

In one form, the power circuit 150 includes power electronic module 190 (i.e., charge station (CS) PEM) and a battery 192. The CS PEM 190 may include an inverter for converting the AC power from the build power network 170 to DC power for the battery pack 102 and a rectifier for converting DC power to AC power. In one form, the battery 192 is a low voltage rechargeable battery (e.g., 12V, 20V) that provides power to components within the charge station 104. FIG. 1 illustrates a simple diagram of the power circuit 150, and it should be readily understood that the power circuit 150 includes additional components for transferring power between the EV 100 and the installed power source, such as the building power network 170, and should not be limited to the example provided here.

The charge station 104 further includes a (CS) communication system (Comm. Sys.) 200, one or more (CS) human machine interfaces (HMIs) 202, and a (CS) controller 204, where “CS” is “charge station” distinguish from similar components of the EV 100. The CS communication system 200 is configured to communicate with external devices like, but not limited to, the portable computing device 132 having a charge station software application 205 and the CSS 134. In a non-limiting example, the CS communication system 200 may establish communication using BLUETOOTH protocol, a WiFi network, satellite communication, and may include antenna, router, modem, among other components (e.g., microprocessor configured with communication protocols).

In one form, the CS HMIs 202 are configured to exchange information with a user and may include, but is not limited to, a touchscreen display 202A, one or more illumination device 202B (e.g., LEDs) that illuminate to identify a status of a specific function and/or component, and/or one or more push buttons 202C (e.g., one of the push buttons is a TC button that places the charge station in a TC mode when operated). For example, the touchscreen may provide information on a charging status of the EV 100, an operation mode of the charge station 104 (e.g., charging, TC mode, providing power). The illumination devices 202B may be used to indicate if certain sensors are operating or whether certain communication mediums are not operating (e.g., no WiFi).

In one form, the CS controller 204 is configured to operate the charge station 104 based on whether the EV 100 is to be charged or provide power. Specifically, like the controller 130, the CS controller 204 detects whether the charge station 104 is connected to the EV 100 using a proximity pin provided at the charger 112 and exchanges information with the controller 130 via a control pilot of the charger 112 to determine whether the battery pack 102 is to provide power or is to be charged. In FIG. 1, lines 210, 212 represent communication coupling of the proximity pin 122 and the control pilot 124 with associated terminals of the charger 112, respectively, and lines 214, 216 represent communication coupling of proximity pin and control pilot of the charger 112 with the CS controller 204.

In addition to controlling power transfer between the EV 100 and the installed power source, the CS controller 204 is configured to operate in a TC mode to execute one or more software-based tasks. Specifically, using the bidirectional transfer energy, the charge station 104 is configured to operate in the TC mode without having to be connected to the installed power source. This allows the charge station 104 to undergo testing/configuration in various situations. In one form, the software-based tasks may include, but is not limited to, component or system level tests (e.g., testing whether the CS communication system 204 is able to communicate via WiFi, pinging sensors within the charge station 104, etc.), software configuration, and software update. In a non-limiting example, when the charge station 104 is not yet installed, the charge station may still perform software-based tasks to, for example, validate components within the charge station 104, and/or check communication capability. Accordingly, if a fault is detected, the charge station 104 may undergo repairs prior to installation. Conversely, if no fault is detected, but the charge station 104 is not operating as intended after installation, then the user may rule out the charge station 104 as the cause of the error. In yet another example, after the charge station 104 is installed and fault occurs, the charge station 104 may be disconnected from the installed power source before the charge station 104 is evaluated. Accordingly, using power from the EV 100, which may be a service vehicle, the charge station 104 may transition to TC mode to undergo evaluation.

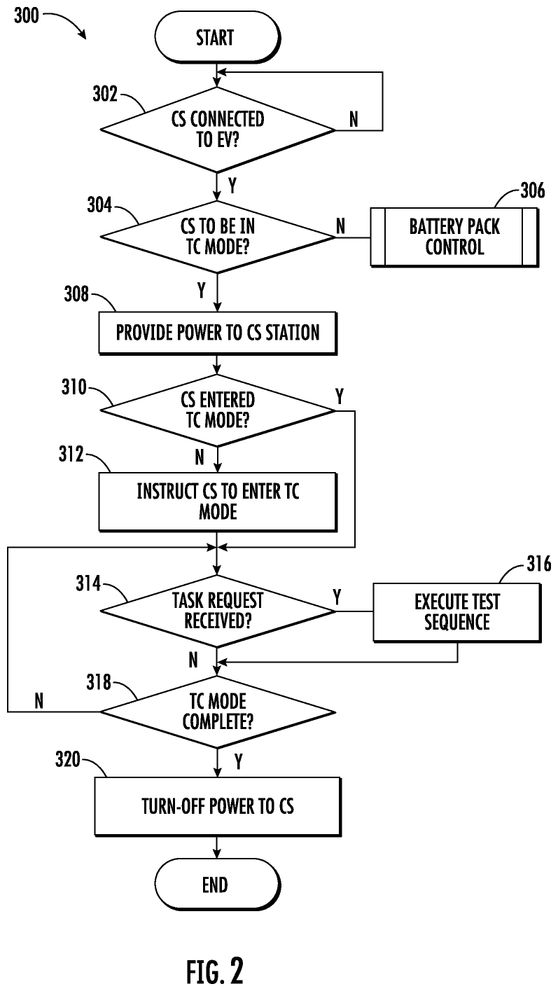

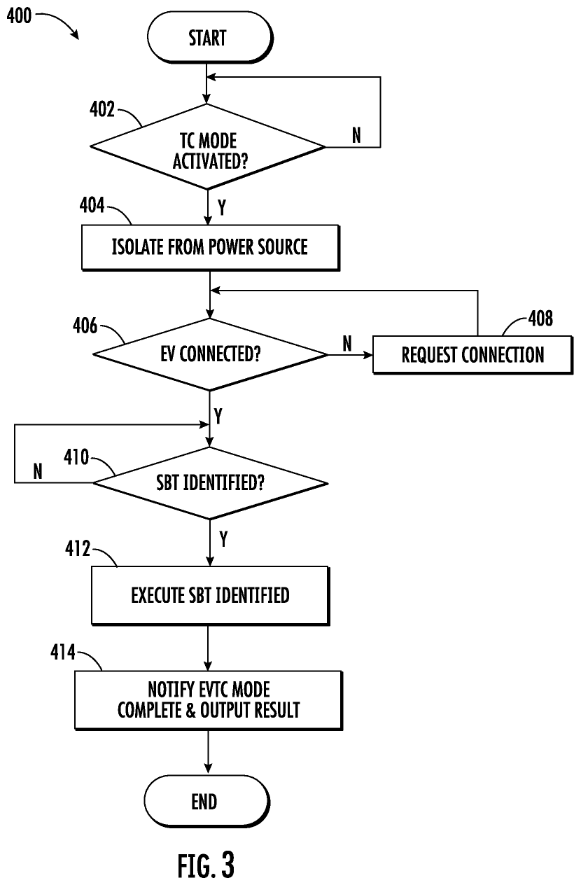

Referring to FIGS. 2 and 3, an example electric vehicle test-configuration (EVTC) routine 300 performed by the EV 100 and a CSTC routine 400 performed by the charge station 104 is provided. At operation 302, the EV 100 determines if the charge station 104 is connected based on a signal from the proximity pin 122. If connected, the EV 100 determines if the TC mode is requested, at operation 304. As provided above, the T-C mode may be detected in various suitable ways, including but not limited to operation of the CSTC switch 140 and/or a message from the charge station 104 via the control pilot 124. If the TC mode is not requested, the EV 100 proceeds to a battery pack control at operation 306 to control the battery pack (i.e., charge/supply power).

If the TC mode is requested, the EV 100 supplies power to the charge station 104 at operation 308, and determines if the charge station entered TC mode at operation 310. In a non-limiting example, the EV 100 may determine if the charge station 104 entered the TC mode based on a message received from the charge station 104. If no message is received, the EV 100 instructs the charge station 104 to enter the TC mode at operation 312. In return, the charge station 104 may enter the TC mode once it receives the message from the EV 100, an external device.

At operation 314, the EV 100 determines if a task request is received from the charge station 104. In a non-limiting example, the charge station 104 may have the EV 100 take part in a specific test, and the message from the charge station 104 may identify the specific test, which may be stored in the controller 130. If the test is received, the EV 100 executes the test at operation 316. In one example, the test may be a communication test in which the charge station 104 is evaluating whether the CS communication system 200 is able to communicate via one or more protocols such as but no limited to, WiFi and/or BLUETOOTH. In the communication test, the EV 100 transmits a request to communicate using the selected protocol, and if confirmation is received from the charge station 104, the EV 100 may determine that the communication system 200 is operating. On the other hand, if a confirmation is not received, the EV 100 determines that the test for the selected protocol was not successful.

If no task request is received or after the execution of a selected test, the EV 100 determines if the TC mode is complete, at operation 318. In a non-limiting example, the EV 100 may determine that the TC mode is complete if the CSTC switch 140 is operated and/or if a message from the charge station 104 is received. If the TC mode is not complete, the EV 100 returns to operation 314. If the TC mode is complete, the EV 100 stops power to the charge station 104, at operation 320. In some instances, if the EV 100 took part in a test, the EV 100 may output a message including data indicative of a test result (i.e., a task result) for a test (i.e., the software-based task). In another example, the EV 100 may also receive message from the charge station 104 via the control pilot or the CS communication system 200 indicating the results of the software-based tasks executed, and the EV 100 may display information indicative of the message via the HMIs 126, which is received by the user.

The EVTC routine 300 may be configured in various suitable ways and is not intended to be limited to the operations of FIG. 2. For example, with EV 100 communicating with the charge station 104 (e.g., using control pilot 124 or communication system 128), the EV 100 may be configured to transmit a task sequence that identifies one or more software-based tasks to be performed to the charge station 104 once the charge station 104 is in the TC mode.

In yet another example, the controller 130 of the EV 100 is configured to have the charge station software application 205 that is configured to store the software-based tasks available for execution by the charge station 104 and provides a series of graphical interfaces that allows the user to select the tasks to be executed and receive results. Accordingly, the EV 100 is configured to direct the charge station 104 through the TC mode based on inputs from the user.

Referring to FIG. 3, at operation 402 of the CSTC routine 400, the charge station 104 is configured to determine if TC mode is to be activated, at operation 402. In a non-limiting example, the charge station 104 may detect the TC mode when power is supplied from the EV 100 and the charge station 104 is isolated from the installed power source (e.g., relays 182A, 182B are not connected to power lines 180); when the TC mode button is operated by the user; and/or a message is received from the EV 100 to enter TC mode. If the charge station 104 determines it is not to enter the TC mode, the routine 400 waits until the TC mode is requested, as a default state. Alternatively, if the charge station 104 is not yet installed, the charge station 104 may go into a sleep mode for a selected period of time or until a signal is received. Similarly, if the charge station 104 is connected to EV 100 and has not received a signal from the EV 100, the charge station 104 may enter sleep mode. In yet another scenario, if the charge station 104 is installed, the routine 400 may be configured to have the charge station 104 detect if the charger 112 is connected to the EV 100 and operate as intended to control power to/from the EV 100.

If the TC mode is to be activated, the charge station 104, at operation 404, isolates from the installed power source by, for example, detecting and having the relays 182A, 182B open. If the charge station 104 is not yet installed, the relays 182A are already open and stay open. At operation 406, the charge station 104 is configured to detect if the EV 100 is not connected via, for example, the proximity pin. If the EV 100 is not connected, the charge station 104 is configured to display a message via the HMIs (e.g., illuminate an illumination device 202B or display a message on the touchscreen 202A) requesting the EV 100 to be connected, at operation 408.

Once connected, the charge station 104 receives power from the EV 100, and determines if the software-based tasks (SBTs) to be performed are identified at operation 410. In a non-limiting example, the charge station 104 may receive a task sequence that identifies the software-based tasks to be performed by the user via the HMIs 202. In another example, if the charge station 104 is in communication with the EV 100 via the CS communication system 200, the charge station 104 may receive the task sequence from the EV 100.

At operation 412, the charge station 104 performs the software-based tasks identified and once complete, notifies the EV 100 that the TC mode is complete and outputs the results, at operation 414. More specifically, at operation 412, the charge station 104 performs each subprogram associated with each of the tasks, and outputs results associated with each task. At any time during execution of the task, the charge station 104 may communicate information with the user via, for example, the HMIs 202 and/or the EV 100. Furthermore, if required by the selected task, the charge station 104 may transmit a task request to the EV 100 requesting the EV 100 to perform the selected task. In a non-limiting example, the results outputted by the charge station 104 may indicate: whether the task performed was completed or incomplete; whether a selected component associated with the task is operating as intended (e.g., did a sensor operate as intended); and/or whether a component associated with the task is to be analyzed further.

The CSTC routine 300 may be configured in various suitable ways and is not intended to be limited to the operations of FIG. 3. In a non-limiting example, the charge station 104 may be configured to have one or more task sequences that are executed at selected installation stages of the charge station 104, and thus, once the TC mode is entered, the software-based tasked to be performed are automatically identified at operation 410 based on the task sequence that is to be executed next. Once completed, the task sequence is identified as being done. In yet another example, the charge station 104 may be configured to join the vehicle wireless communication network (e.g., Wi-Fi, BLUETHOOTH, ZigBee, Z-Wave) to communicate with external devices such as, the EV 100, the portable computing device 132, and/or the CSS 134. This enables the charge station 104 to exchange messages related to the TC mode even if the charge station 104 is not installed and/or connected to a building wireless communication network.

In some variations, the CSS 134 is configured to track and monitor multiple charge stations 104, and, using a web-based interface or the charge station application 205, the user is able access information of the CSS 134. In a non-limiting example, the CSS 134 is supported by the maker of the charge station 104, maker of the EV 100, and/or an entity that owns the charge stations 104. As a remote server, the CSS 134 is configured to communicate with other systems including the charge station 104, the EV 100, and the charge station application 205.

In one form, the CSS 134 is configured to also include a charge station library (CSL) 220, software-based task library (SBTL) 222, and a charge station manager module (CSMM) 224. The charge station library 220 is configured to store a station record for each charge station 104, where the station record includes information such as, but not limited to: unique identification of the charge station 104, location information of the charge station 104, software profile indicating version history of the software/firmware on the charge station; hardware profile indicating part name and number of components that make up the charge station 104; and operation history which may provide charge operations, detected faults, and communication exchanges with the CSS 134. The SBTL 222 is configured to store software-based tasks for the charge stations 104, such as, but not limited to: tests to check operation and/or performance of the charge station 104 as a whole and/or of specific components; and software or firmware programs to be employed by the charge stations 104.

The CSMM 224 is configured to track and monitor the charge stations 104 by, for example, determining whether firmware/software of the charge station 104 is to be updated, and periodically communicating with the charge station 104 to check operation state of the charge station. In some forms, the CSMM 224 may also process messages from other systems that may request information regarding a selected charge station and software programs associated with identified software-based tasks. In a non-limiting example, the charge station 104 may request the CSMM 224 to provide software programs associated with identified software-based tasks to be executed during the T-M mode.

In some variations, the charge station application 205 accesses the information in the CSS 134 to control the charge station 104 for the TC mode. In a non-limiting example, based on inputs from the user, the charge station application 205 communicates with the charge station 104 to initiate the TC mode, identifies software-based tasks to be performed, instructs the charge station 104 to execute the selected software-based tasks, obtains result of the tasks from the charge station 104, and outputs a message including data indicative of the result for the task (i.e., identified software-based tasks) to the CSS 134.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read only circuit), volatile memory circuits (such as a static random access memory circuit or a dynamic random access memory circuit), magnetic storage media (such as an analog or digital magnetic tape or a hard disk drive), and optical storage media (such as a USB drive, CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method, comprising:
supplying, by an electric vehicle (EV), electrical power to an EV charge station; and
outputting a message including data indicative of a task result for a software-based task performed at the EV charge station with the EV charge station receiving power from the EV.

2. The method of claim 1, further comprising communicably coupling the EV charge station to a wireless communication network supported by the EV.

3. The method of claim 2, wherein outputting the message further comprises transmitting, by the EV charge station, the message to a remote server via the wireless communication network supported by the EV.

4. The method of claim 1, further comprising instructing, by an external device, execution of the software-based task in response to the EV charge station not executing the software-based task automatically after receiving power from the EV.

5. The method of claim 4, wherein the external device is at least one of the EV or a portable computing device having a software application configured to provide commands to the EV charge station to have the EV charge station initiate execution of the software-based task stored at at least one of the EV charge station, a remove server, or the EV.

6. The method of claim 1, wherein outputting the message further comprises, at least one:
transmitting the message to a remote server; or
providing the message via one or more human machine interface devices.

7. The method of claim 1, wherein the software-based task is at least one of a software upgrade or diagnostic test.

8. The method of claim 7, wherein the diagnostic test includes tests evaluating, at least one of, a circuit board or a communication connection.

9. The method of claim 1, wherein supplying electrical power to the EV charge station further comprises having a charger of the EV charge station connected to a charge port of the EV with the EV charge station being isolated from a power grid.

10. The method of claim 1, further comprising electrically coupling the EV charge station to a power grid in response to the task result indicating a nominal result of the EV charge station.

11. A system comprising
one or more controllers configured to:
control a power electronics module to supply electric power to an electric vehicle (EV) charge station from a battery pack of an EV; and
output a message including data indicative of a task result for a software-based task performed at the EV charge station with the EV charge station receiving electric power from the EV.

12. The system of claim 11, wherein the one or more controllers is further configured to communicably couple the EV charge station to a wireless communication network supported by the EV.

13. The system of claim 12, wherein the one or more controllers is further configured to transmit the message to a remote server via the wireless communication network supported by the EV.

14. The system of claim 11, wherein the one or more controllers is further configured to instruct execution of the software-based task in response to the EV charge station not executing the software-based task automatically after receiving power from the EV.

15. The system of claim 11, wherein the one or more controllers is further configured to provide the message to one or more human machine interface devices.

16. The system of claim 11, wherein the software-based task is at least one of a software upgrade or diagnostic test.

17. The system of claim 16, wherein the diagnostic test includes tests evaluating, at least one of, a circuit board or a communication connection.

18. The system of claim 11, wherein at least one of the one or more controllers is provided at the EV and at least one of the one or more controllers is provided at the EV charge station.

19. The system of claim 11, wherein the one or more controllers is configured to detect a charger of the EV charge station connected to a charge port of the EV and controls power to the EV charge station in response to detecting the charger being connected to the charge port.

20. A method, comprising:
supplying, by an electric vehicle (EV), alternating current (AC) power to an EV charge station after detecting a charger of the EV charge station connected to a charge port of the EV and having the EV charge station electrically isolated from an installed power source;
having at least one software-based task performed at the EV charge station after supplying power to the EV charge station; and
outputting a message to at least one of a remote server or a human machine interface, the message including data indicative of a task result for the at least one software-based task performed at the EV charge station.
